(19) United States
(12) Patent Application Publication
(10) Pub. No.: US 2026/0282370 A1
(43) Pub. Date: Sep. 17, 2026

(54) SEMICONDUCTOR DEVICE AND MANUFACTURING METHOD THEREOF

(71) Applicant: Kioxia Corporation, Tokyo (JP)

(72) Inventors: Toshitaka MIYATA, Yokkaichi (JP); Shuto YAMASAKA, Yokkaichi (JP)

(73) Assignee: Kioxia Corporation, Tokyo (JP)

(21) Appl. No.: 19/321,471

(22) Filed: Sep. 8, 2025

(30) Foreign Application Priority Data
Mar. 14, 2025 (JP) 2025-041839

(51) Int. Cl. H10B 43/35; H01L 23/00; H01L 23/522; H01L 25/18; H10B 80/00; H10D 80/30; H10D 84/01; H10D 84/85

(52) U.S. Cl. CPC H10B 43/35; H10D 84/0186; H10D 84/859; H10W 20/423; H10B 80/00; H10D 80/30; H10W 90/00; H10W 90/792

(57) ABSTRACT

A semiconductor device of the embodiment includes two structures and two conductors. A plurality of first semiconductor elements are formed in the first structure. The second structure includes a substrate including a plurality of impurity diffused layers, and a plurality of second semiconductor elements located in the impurity diffused layers on the side of a first surface of the substrate, and is stacked on the first structure on the side of a second surface of the substrate on the opposite side to the first surface. The first conductor is located between the first structure and the second structure, is electrically separated from the substrate, and is electrically connected to at least one of the first semiconductor elements. The second conductor is located between the first conductor and the impurity diffused layers, and shields at least a portion of the impurity diffused layers from an electric field of the first conductor.

### CROSS REFERENCE TO RELATED APPLICATIONS

This application is based upon and claims the benefit of priority from the prior Japanese Patent Application No. 2025-041839, filed on Mar. 14, 2025, the entire contents of which are incorporated herein by reference.

### FIELD

The embodiments of the present invention relate to a semiconductor device and a manufacturing method thereof.

### BACKGROUND

Some semiconductor storage devices such as a NAND flash memory have a stacked structure including an array chip where a memory cell array is arranged, and a CMOS (Complementary Metal Oxide Semiconductor) chip where a CMOS circuit is arranged.

### BRIEF DESCRIPTION OF THE DRAWINGS

FIG. 1 is a block diagram illustrating a configuration example of a storage device according to a first embodiment;

FIG. 2 is a block diagram illustrating a configuration example of the storage device according to the first embodiment;

FIG. 3 is a perspective view illustrating a configuration example of the storage device according to the first embodiment;

FIG. 4 is a conceptual diagram illustrating a configuration example of the storage device according to the first embodiment;

FIG. 5 is a sectional view illustrating a configuration example of the storage device according to the first embodiment;

FIG. 6 is a sectional view illustrating a configuration example of a memory pillar of the storage device according to the first embodiment;

FIG. 7A is a sectional view illustrating a configuration example of a second structure according to the first embodiment;

FIG. 7B is a sectional view illustrating a configuration example of a second structure according to a modification of the first embodiment;

FIG. 8 is a plan view of a configuration example of a second structure according to another modification of the first embodiment;

FIG. 9 is a sectional view illustrating one example of a manufacturing method of the second structure of the storage device according to the first embodiment;

FIG. 10 is a sectional view illustrating one example of the manufacturing method of the second structure of the storage device, in continuation from FIG. 9;

FIG. 11 is a sectional view illustrating one example of the manufacturing method of the second structure of the storage device, in continuation from FIG. 10;

FIG. 12 is a sectional view illustrating one example of the manufacturing method of the second structure of the storage device, in continuation from FIG. 11;

FIG. 13 is a sectional view illustrating one example of the manufacturing method of the second structure of the storage device, in continuation from FIG. 12;

FIG. 14 is a sectional view illustrating one example of the manufacturing method of the second structure of the storage device, in continuation from FIG. 13;

FIG. 15 is a sectional view illustrating one example of the manufacturing method of the second structure of the storage device, in continuation from FIG. 14;

FIG. 16 is a sectional view illustrating one example of the manufacturing method of the second structure of the storage device, in continuation from FIG. 15;

FIG. 17 is a sectional view illustrating a configuration example of a second structure according to a second embodiment;

FIG. 18 is a sectional view illustrating a configuration example of a second structure according to a third embodiment;

FIG. 19 is a sectional view illustrating one example of a manufacturing method of the second structure of the storage device according to the third embodiment;

FIG. 20 is a sectional view illustrating one example of the manufacturing method of the second structure of the storage device, in continuation from FIG. 19;

FIG. 21 is a sectional view illustrating one example of the manufacturing method of the second structure of the storage device, in continuation from FIG. 20;

FIG. 22 is a sectional view illustrating a configuration example of a second structure according to a fourth embodiment;

FIG. 23 is a sectional view illustrating one example of a manufacturing method of the second structure of the storage device according to the fourth embodiment;

FIG. 24 is a sectional view illustrating a configuration example of a second structure according to a fifth embodiment;

FIG. 25 is a sectional view illustrating a configuration example of a second structure according to a sixth embodiment;

FIG. 26 is a plan view of a substrate according to the sixth embodiment; and

FIG. 27 is a sectional view illustrating a configuration example of a storage device according to a seventh embodiment.

### DETAILED DESCRIPTION

In general, a semiconductor device according to the present embodiment includes a first structure, a second structure, a first conductor, and a second conductor. A plurality of first semiconductor elements are formed in the first structure. The second structure includes a substrate including a plurality of impurity diffused layers, and a plurality of second semiconductor elements located in the impurity diffused layers on the side of a first surface of the substrate, and is stacked on the first structure on the side of a second surface of the substrate on the opposite side to the first surface. The first conductor is located between the first structure and the second structure, is electrically separated from the substrate, and is electrically connected to at least one of the first semiconductor elements. The second conductor is located between the first conductor and the impurity diffused layers, and shields at least a portion of the impurity diffused layers from an electric field of the first conductor. Hereinafter, devices of the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

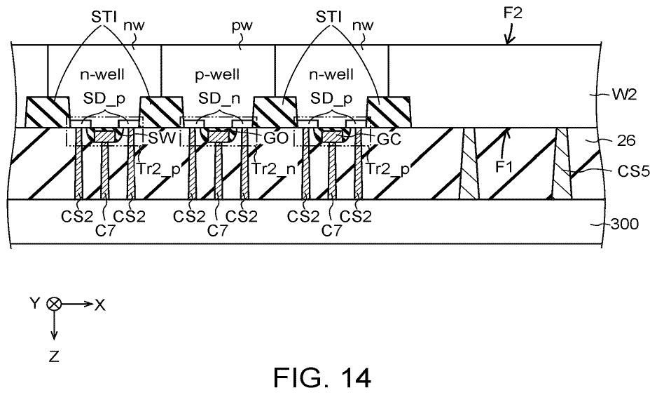

As used in the present specification and the claims, when a first element is “connected” to another second element, the first element can be connected to the second element directly, or via an element that becomes conductive either constantly or selectively. While it is assumed that a +Z direction is an upward direction and a −Z direction is a downward direction in the present specification and the drawings, it is sometimes assumed in FIGS. 14 to 16, 19 to 21, and 23 that the −Z direction is conversely the upward direction and the +Z direction is the downward direction. The Z direction is an example of a first direction and a stacking direction.

### First Embodiment

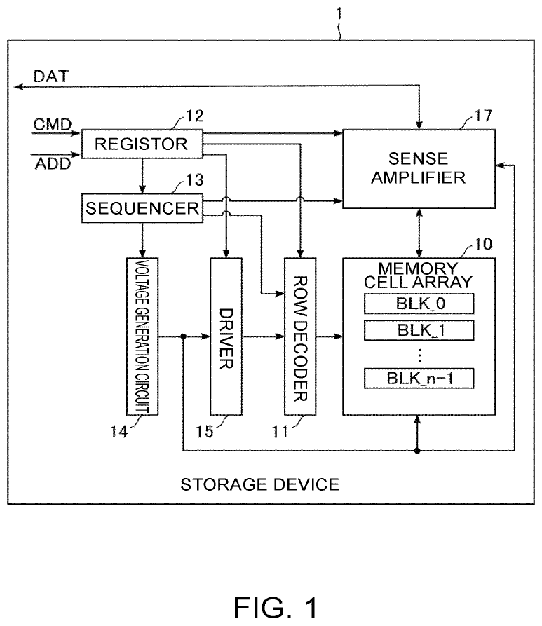

FIG. 1 is a block diagram illustrating a configuration example of a storage device 1 according to a first embodiment. The storage device 1 as one example of a semiconductor device is a device that stores therein data using memory cells. The storage device 1 is, for example, a NAND flash memory. The storage device 1 is controlled by an external memory controller. The storage device 1 operates, for example, based on a command CMD and address information ADD received from the memory controller. The storage device 1 receives data DAT to be written, and outputs data stored in the storage device 1.

The storage device 1 includes constituent elements such as a memory cell array 10, row decoders 11, a register 12, a sequencer 13, a voltage generation circuit 14, a driver 15, and a sense amplifier 17.

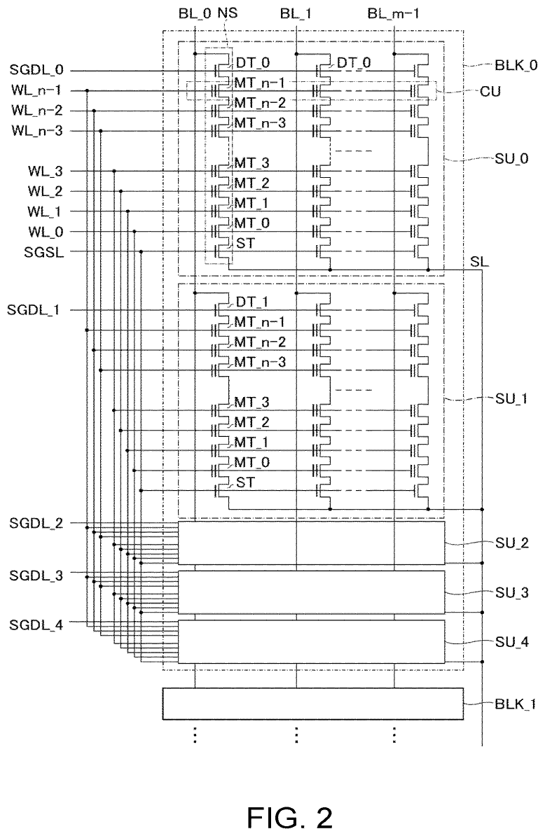

The memory cell array 10 is a set of arrayed memory cells. The memory cell array 10 includes a plurality of memory blocks (blocks) BLK. Each block BLK includes a plurality of memory cell transistors MT (see FIG. 2). A region where the memory cell array 10 is arranged also includes lines such as word lines WL (see FIG. 2) and bit lines BL (see FIG. 2).

The row decoders 11 are circuits for selecting a block BLK. The row decoders 11 transfer a voltage supplied from the driver 15 to one block BLK selected based on a block address received by the row decoders 11 from the register 12.

The register 12 is a circuit that retains a command CMD and address information ADD received by the storage device 1. The command CMD instructs various operations including a data read operation, a data write operation, and a data erase operation to the sequencer 13. The address information ADD designates an access target in the memory cell array 10.

The sequencer 13 is a circuit that controls the entire operation of the storage device 1. The sequencer 13 controls the row decoders 11, the driver 15, and the sense amplifier 17 on the basis of the command CMD received by the sequencer 13 to perform various operations including a data read operation, a data write operation, and a data erase operation.

The voltage generation circuit 14 is a circuit that generates different levels of voltages. The voltage generation circuit 14 receives a power voltage from outside the storage device 1 and generates voltages from the power voltage. The voltage generation circuit 14 supplies the generated voltages to constituent elements such as the memory cell array 10, the driver 15, and the sense amplifier 17.

The driver 15 is a circuit that applies various voltages required for the operation of the storage device 1 to some constituent elements. The driver 15 receives plural voltages from the voltage generation circuit 14 and supplies selected ones of the voltages to one or more row decoders 11.

The sense amplifier 17 is a circuit that outputs a signal based on data stored in the memory cell array 10. The sense amplifier 17 senses the state of a relevant memory cell transistor MT (hereinafter, also simply “memory cell”) and generates read data on the basis of the sensed state. The sense amplifier 17 applies a voltage based on data to be written, to a bit line BL.

FIG. 2 is a block diagram illustrating a configuration example of the storage device according to the first embodiment. A plurality of the blocks BLK, for example, all the blocks BLK include constituent elements and connections illustrated in FIG. 2.

One block BLK includes a plurality of string units SU. FIG. 2 illustrates an example of five string units SU_0 to SU_4.

As illustrated in FIG. 2, each of m bit lines BL_0 to BL_m-1 is connected to one NAND string NS in each of the string units SU_0 to SU_4 in each block BLK. In this example, m is a positive integer.

Each NAND string NS includes one selection gate transistor ST, n memory cell transistors MT (MT_0 to MT_n-1), and one selection gate transistor DT (DT_0, DT_1, DT_2, DT_3, or DT_4). In this example, n is a positive integer. Each of the memory cell transistors MT is an element that functions as a memory cell and stores therein data in a nonvolatile manner. Each memory cell transistor MT includes a control gate electrode or a gate electrode (a word line WL) and a charge accumulation film insulated from the peripheral part, and stores therein data in a nonvolatile manner on the basis of charges in the charge accumulation film. Data is written to each of the memory cell transistors MT by injection of electrons into the charge accumulation film.

The selection gate transistor ST, the memory cell transistors MT_0 to MT_n-1, and the selection gate transistor DT are connected in series in this order between a source line SL and one bit line BL.

A plurality of NAND strings NS respectively connected to a plurality of different bit lines BL constitute one string unit SU. In each string unit SU, the control gate electrodes of the memory cell transistors MT_0 to MT_n-1 are connected to word lines WL_0 to WL_n-1, respectively. A set of memory cell transistors MT sharing a word line WL in one string unit SU is referred to as “cell unit CU”.

The selection gate transistors DT_0 to DT_4 belong to the string units SU_0 to SU_4, respectively. In FIG. 2, illustrations of the selection gate transistors DT_2, DT_3, and DT_4 are omitted. The gates of the selection gate transistors DT_0 in the NAND strings NS in the string unit SU_0 are connected to a selection gate line SGDL_0. Similarly, the gates of the selection gate transistors DT_1, DT_2, DT_3, and DT_4 in the associated NAND strings NS in the string units SU_1, SU_2, SU_3, and SU_4 are connected to selection gate lines SGDL_1, SGDL_2, SGDL_3, and SGDL_4, respectively.

The gates of the selection gate transistors ST are connected to a selection gate line SGSL.

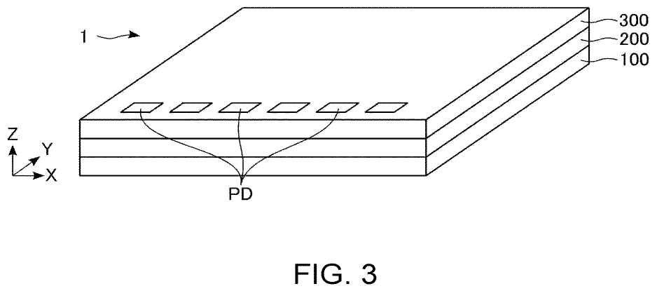

FIG. 3 is a perspective view illustrating a configuration example of the storage device according to the first embodiment. The storage device 1 includes a first structure 100, a second structure 200, and a third structure 300. The first structure 100, the second structure 200, and the third structure 300 spread along an XY plane and are stacked in the Z direction. The second structure 200 is located on a surface (the upper surface) of the first structure 100 on a side in the Z direction. The third structure 300 is located on the upper surface of the second structure 200.

Each of the first structure 100, the second structure 200, and the third structure 300 includes a plurality of semiconductors, a plurality of various conductors, and a plurality of insulators formed on a substrate using the substrate. Each of the first structure 100, the second structure 200, and the third structure 300 includes a plurality of elements and lines realized by semiconductors, conductors, and insulators. Each of the first structure 100, the second structure 200, and the third structure 300 includes an electrical circuit including elements and lines. The elements and lines in the first structure 100, the elements and lines in the second structure 200, and the elements and lines in the third structure 300 are electrically connected to each other. Each of the first structure 100, the second structure 200, and the third structure 300 is formed as an individual semiconductor chip. The first structure 100, the second structure 200, and the third structure 300 are bonded to each other to be a semiconductor chip of one storage device 1.

A set of the first structure 100 and the second structure 200 includes the row decoders 11, the register 12, the sequencer 13, the voltage generation circuit 14, the driver 15, and the sense amplifier 17. The first structure 100 includes any constituent elements among the row decoders 11, the register 12, the sequencer 13, the voltage generation circuit 14, the driver 15, and the sense amplifier 17. The second structure 200 includes any constituent elements among the row decoders 11, the register 12, the sequencer 13, the voltage generation circuit 14, the driver 15, and the sense amplifier 17. For example, the first structure 100 includes semiconductor elements constituting the row decoders 11, the register 12, the sequencer 13, the voltage generation circuit 14, and the driver 15. The second structure 200 includes semiconductor elements constituting the sense amplifier 17. Each of the row decoders 11, the register 12, the sequencer 13, the voltage generation circuit 14, the driver 15, and the sense amplifier 17 is constituted of a CMOS circuit including a p-type MOSFET (Metal Oxide Semiconductor Field Effect Transistor) and an n-type MOSFET. Each of the first structure 100 and the second structure 200 is, for example, a CMOS chip including such a CMOS circuit.

The third structure 300 is, for example, an array chip including the memory cell array 10 and a plurality of external connection terminals PD. The external connection terminals PD are exposed on the upper surface of the third structure 300.

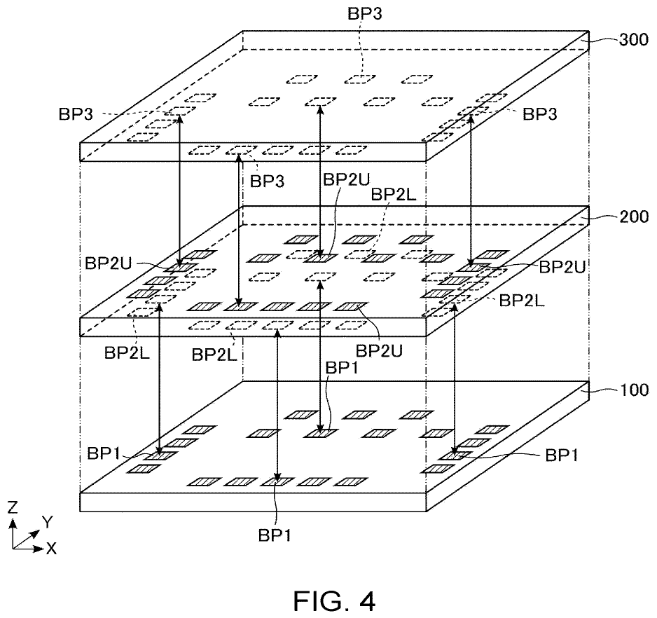

FIG. 4 is a conceptual diagram illustrating a configuration example of the storage device according to the first embodiment. FIG. 4 illustrates the structure illustrated in FIG. 3 in an exploded manner.

The first structure 100 includes a plurality of conductive joint terminals BP1. The joint terminals BP1 are exposed on the upper surface of the first structure 100. The joint terminals BP1 are connected to the elements in the first structure 100.

The second structure 200 includes a plurality of conductive joint terminals BP2L and a plurality of conductive joint terminals BP2U. The joint terminals BP2L are exposed on a surface (the lower surface) of the second structure 200 on a side in the −Z direction. The joint terminals BP2L are connected to the elements in the second structure 200. The joint terminals BP2L have the same layout as that of the joint terminals BP1 of the first structure 100. The joint terminals BP2L are arrayed in such a manner that each of the joint terminals BP2L is in contact with one of the joint terminals BP1 of the first structure 100 corresponding to this joint terminal BP2L when the first structure 100 and the second structure 200 are joined to each other. A certain joint terminal BP2L and one of the joint terminals BP1 of the first structure 100 corresponding to the certain joint terminal BP2L are elements functioning as the same node in a circuit.

The joint terminals BP2U are exposed on the upper surface of the second structure 200. The joint terminals BP2U are connected to the elements in the second structure 200.

The third structure 300 includes a plurality of conductive joint terminals BP3. The joint terminals BP3 are exposed on the lower surface of the third structure 300. The joint terminals BP3 are connected to the elements in the third structure 300. The joint terminals BP3 have the same layout as that of the joint terminals BP2U of the second structure 200. The joint terminals BP3 are arrayed in such a manner that each of the joint terminals BP3 is in contact with one of the joint terminals BP2U of the second structure 200 corresponding to this joint terminal BP3 when the second structure 200 and the third structure 300 are joined to each other. A certain joint terminal BP3 and one of the joint terminals BP2U of the second structure 200 corresponding to the certain joint terminal BP3 are elements functioning as the same node in a circuit.

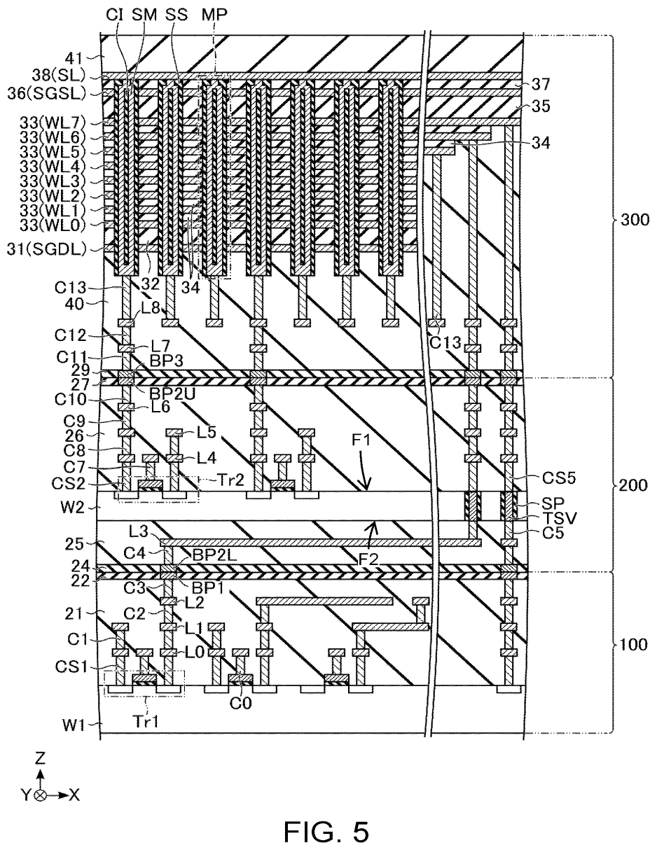

FIG. 5 is a sectional view illustrating a configuration example of the storage device according to the first embodiment. The first structure 100 is bonded to the second structure 200 on the side of a second surface F2 of a substrate W2 to be stacked thereon. The third structure 300 is bonded to the second structure 200 on the side of a first surface F1 of the substrate W2 to be stacked thereon.

The first structure 100 further includes a substrate W1, transistors Tr1, contacts CS1, C0, C1, C2, and C3, conductors L0, L1, and L2, and insulators 21 and 22. In the following descriptions, conductors also include semiconductors having a conductivity due to inclusion of a metallic material or impurities. In one example, the substrate W1 includes silicon. In one example, each of the contacts CS1, C0, C1, C2, and C3 and the conductors L0, L1, and L2 includes copper or tungsten. In one example, each of the insulators 21 and 22 includes silicon oxide.

The transistors Tr1 are positioned in a region of an upper part of the substrate W1 and near the upper surface. Each of the transistors Tr1 includes a gate insulator on the upper surface of the substrate W1, a gate electrode on the upper surface of the gate insulator, and a region (source/drain region) of one pair of a source and a drain sandwiching a region below the gate electrode. Each of the transistors Tr1 is electrically connected to any of conductors (for example, word lines WL) 31, 33, and 36 via a conductor (for example, a line) L3 and a through-electrode TSV of the second structure 200. Accordingly, the transistors Tr1 of the first structure 100 can constitute the driver (drive circuit) 15 that controls the voltages of the conductors 31, 33, and 36.

Each contact C0 is in contact on the lower surface with the upper surface of the gate electrode of one transistor Tr1. Each contact CS1 is in contact on the lower surface with one source/drain region.

Each conductor L0 is in contact on the lower surface with one contact C0 or CS1. Each contact C1 is in contact on the lower surface with the upper surface of one conductor L0.

Each conductor L1 is in contact on the lower surface with the upper surface of one contact C1. Each contact C2 is in contact on the lower surface with the upper surface of one conductor L1.

Each conductor L2 is in contact on the lower surface with the upper surface of one contact C2. Each contact C3 is in contact on the lower surface with the upper surface of one conductor L2.

A set of the transistor Tr1, the contacts CS1, C0, C1, C2, and C3, and the conductors L0, L1, and L2 realizes a circuit included in the first structure 100. Therefore, the first structure 100 has any shapes and arrangement of the transistors Tr1, the contacts CS1, C0, C1, C2, and C3, and the conductors L0, L1, and L2 realizing circuits included in the first structure 100.

The insulator 21 is arranged from the level of the upper surface of the substrate W1 to the level of the upper surfaces of the contacts C3. The insulator 21 fills a region where the constituent elements are not arranged in the first structure 100, that is, a region where the transistors Tr1, the contacts CS1, C0, C1, C2, and C3, and the conductors L0, L1, and L2 are not arranged.

Each joint terminal BP1 is in contact on the lower surface with the upper surface of one contact C3. The insulator 22 fills a region where the joint terminals BP1 are not located in a layer where the joint terminals BP1 are positioned.

The second structure 200 further includes the substrate W2, transistors Tr2, contacts CS2, CS5, C4, C5, C7, C8, C9, and C10, conductors L3, L4, L5, and L6, and insulators 24, 25, 26, and 27. The substrate W2 includes the first surface F1, and the second surface F2 on the opposite side to the first surface F1. In one example, the substrate W2 includes silicon. The thickness of the substrate W2 is, for example, 0.2 to 2 μm (micrometer). In one example, each of the contacts CS2, CS5, C4, C5, C7, C8, C9, and C10, and the conductors L3, L4, L5, and L6 includes copper or tungsten. In one example, each of the insulators 24, 25, 26, and 27 includes silicon oxide. The upper surface of the second structure 200 is on the side of the first surface F1 of the substrate W2 and the lower surface of the second structure 200 is on the side of the second surface F2 of the substrate W2.

Each joint terminal BP2L is positioned in the lowermost layer of the second structure 200. The insulator 24 fills a region where the joint terminals BP2L are not located in the layer where the joint terminals BP2L are positioned.

Each contact C4 is in contact on the lower surface with the upper surface of one joint terminal BP2L.

Each conductor L3 is in contact on the lower surface with the upper surface of one contact C4. In one example, each of the conductors L3 includes copper (Cu), aluminum (Al), and (or) tungsten (W). Each contact C5 is in contact on the lower surface with the upper surface of one conductor L3. The conductors L3 are electrically connected to the voltage generation circuit 14 to receive a high positive voltage. The conductors L3 are arranged on the side of the second surface F2 of the substrate W2 with the insulator 25 interposed therebetween. Each of the conductors L3 is electrically connected to a transistor Tr1 in the first structure 100 via the contact C4 and the like. The conductors L3 are located between the first structure 100 and the second structure 200 and are electrically insulated from the substrate W2 by the insulator 25. Each of the conductors L3 is electrically connected to conductors 31, 33, or 36 of the third structure 300 via a through-electrode TSV and the like.

The insulator 25 is arranged from the level of the upper surfaces of the joint terminals BP2L and the upper surface of the insulator 24 to the level of the upper surfaces of the contacts C5. The insulator 25 fills a region where the contacts C4 and C5, and the conductors L3 are not arranged in a region above the joint terminals BP2L and the insulator 24.

The substrate W2 is positioned on the upper surface of the insulator 25. The through-electrodes TSV penetrate through the substrate W2 from the upper surface of the substrate W2 to the lower surface thereof. Each through-electrode TSV is in contact on the lower surface with the upper surface of one contact C5. Insulators SP penetrate through the substrate W2 from the upper surface of the substrate W2 to the lower surface thereof. Each insulator SP covers the side surface of one through-electrode TSV. Each of the through-electrodes TSV is electrically separated from the substrate W2 by the insulator SP.

The transistors Tr2 are arranged on the side of the first surface F1 of the substrate W2. Each of the transistors Tr2 includes a gate insulator on the upper surface of the substrate W2, a gate electrode on the upper surface of the gate insulator, and a region (source/drain region) of one pair of a source and a drain sandwiching a region below the gate electrode. Each of the transistors Tr2 is electrically connected to any of semiconductor layers SM of memory pillars MP. Accordingly, the transistors Tr2 of the second structure 200 constitute the sense amplifier 17 that detects data stored in memory cells via the associated semiconductor layers SM of the memory pillars MP.

Each contact C7 is in contact on the lower surface with the upper surface of the gate electrode of one transistor Tr2. Each contact CS2 is in contact on the lower surface with one source/drain region. Each contact CS5 is in contact on the lower surface with the upper surface of one through-electrode TSV.

Each conductor L4 is in contact on the lower surface with the upper surface of one contact C7, CS2, or CS5. Each contact C8 is in contact on the lower surface with the upper surface of one conductor L4.

Each conductor L5 is in contact on the lower surface with the upper surface of one contact C8. Each contact C9 is in contact on the lower surface with the upper surface of one conductor L5.

Each conductor L6 is in contact on the lower surface with the upper surface of one contact C9. Each contact C10 is in contact on the lower surface with the upper surface of one conductor L6.

A set of the transistor Tr2, the contacts CS2, CS5, C4, C5, C7, C8, C9, and C10, and the conductors L3, L4, L5, and L6 realizes a circuit included in the second structure 200. Therefore, the second structure 200 has any shapes and arrangement of the transistors Tr2, the contacts CS2, CS5, C4, C5, C7, C8, C9, and C10, and the conductors L3, L4, L5, and L6 realizing circuits included in the second structure 200.

The insulator 26 extends from the level of the upper surface of the substrate W2 to the level of the upper surfaces of the contacts C10. The insulator 26 fills a region where constituent elements are not arranged in a region from the level of the upper surface of the substrate W2 to the level of the upper surfaces of the contacts C10, that is, a region where the transistors Tr2, the contacts CS2, CS5, C7, C8, C9, and C10, and the conductors L4, L5, and L6 are not arranged.

Each joint terminal BP2U is in contact on the lower surface with the upper surface of one contact C10. The insulator 27 fills a region where the joint terminals BP2U are not located in a layer where the joint terminals BP2U are positioned.

The third structure 300 further includes contacts C11, C12, and C13, conductors L7, L8, 31, 33, 36, and 38, insulators 29, 34, 35, 37, 40, and 41, and memory pillars MP.

Each joint terminals BP3 is positioned in the lowermost layer of the third structure 300. The insulator 29 fills a region where the joint terminals BP3 are not located in the layer where the joint terminals BP3 are positioned.

Each contact C11 is in contact on the lower surface with the upper surface of one joint terminal BP3.

Each conductor L7 is in contact on the lower surface with the upper surface of one contact C11. Each contact C12 is in contact on the lower surface with the upper surface of one conductor L7.

Each conductor L8 is in contact on the lower surface with the upper surface of one contact C12.

The conductor 31 is positioned above the conductors L8. The conductor 31 has a plate-like shape along the XY plane. The conductor 31 functions as at least a part of a selection gate line SGDL. The lower surface of the conductor 31 is exposed and has a stepped terrace at ends.

The insulator 32 is positioned on the upper surface of the conductor 31. The insulator 32 has a plate-like shape along the XY plane.

The conductors 33 and the insulators 34 are stacked alternately one by one in the Z direction on the upper surface of the insulator 32 to constitute a stacked body. The conductors 33 and the insulators 34 each have a plate-like shape along the XY plane. Each conductor 33 functions as at least a part of a word line WL. FIG. 5 illustrates an example where n=8, that is, the number of memory cell transistors MT is eight. The conductors 33 function as at least a part of word lines WL0, WL1, WL2, WL3, WL4, WL5, WL6, and WL7 in this order from the lowermost one, respectively. The lower surface of each conductor 33 is exposed and has a stepped terrace at ends.

The insulator 35 is positioned on the upper surface of the uppermost conductor 33.

The conductor 36 is positioned on the upper surface of the insulator 35. The conductor 36 functions as at least a part of a selection gate line SGSL.

The insulator 37 is positioned on the upper surface of the conductor 36. The conductor 38 is positioned on the upper surface of the insulator 37. The lower surface of the conductor 38 is exposed and has a terrace at ends. The conductor 38 functions as, for example, a source layer.

The memory pillars MP extend along a Z-axis and penetrate through the stacked body including the conductors 31, 33, and 36 and the insulators 32, 34, 35, and 37. Each memory pillar MP includes an insulator CI, the semiconductor layer SM, and a memory film SS penetrating through the stacked body. The semiconductor layer SM covers the side surface of the insulator CI. The memory film SS covers the side surface of the semiconductor layer SM and is located between the semiconductor layer SM and the stacked body. The memory film SS is open at the upper end of the associated memory pillar MP. A part of the semiconductor layer SM is positioned in the opening and is in contact on the upper surface with the conductor 38.

It is also possible that an upper part of each of the memory pillars MP is positioned in the conductor 38, the memory film SS is open at a portion facing the conductor 38, and a part of the conductor 38 is positioned in the opening.

A portion facing the conductor 31 in each memory pillar MP functions as one selection gate transistor DT. A portion facing a conductor 33 in each memory pillar MP functions as one memory cell transistor MT. That is, each of the memory pillars MP constitutes a memory cell at an intersecting portion with one of the conductors 33. A portion facing the conductor 36 in each memory pillar MP functions as one selection gate transistor ST. The lower surface of the semiconductor layer SM is exposed on the lower surface of each memory pillar MP. The upper surface of the semiconductor layer SM is exposed on the upper surface of each memory pillar MP. As described above, the third structure 300 is constituted as an array chip including a memory cell array.

Each contact C13 is in contact on the lower surface with the upper surface of one conductor L8. Each of some contacts C13 is in contact on the upper surface with the lower surface of the semiconductor layer SM of one memory pillar MP. Each of some contacts C13 is in contact on the upper surface with the lower surface of one terrace portion of the conductors 31, 33, and 36.

The insulator 40 extends from the level of the upper surface of the insulator 29 to the level of the upper surface of the conductor 38. The insulator 40 fills a region where constituent elements are not arranged in the third structure 300, that is, a region where the contacts C11, C12, and C13, the conductors L7, L8, 31, 33, 36, and 38, the insulators 40, 32, 34, 35, and 37, and the memory pillars MP are not arranged.

The insulator 41 is positioned on the upper surfaces of the conductor 38 and the insulator 40.

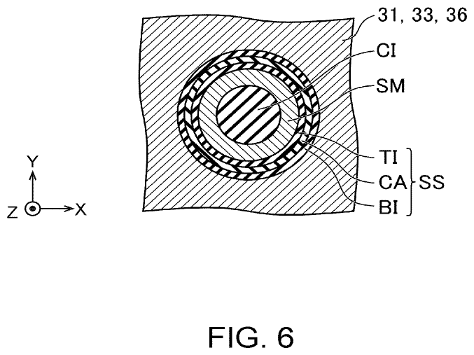

FIG. 6 is a sectional view illustrating a configuration example of a memory pillar of the storage device according to the first embodiment. FIG. 6 illustrates a cross-sectional structure of a memory pillar along the XY plane. In one example, the memory film SS includes a tunnel insulator TI, a charge accumulation film CA, and a block insulator BI.

The tunnel insulator TI surrounds the side surface of the semiconductor layer SM. The charge accumulation film CA surrounds the side surface of the tunnel insulator TI. The block insulator BI surrounds the side surface of the charge accumulation film CA. The conductor 31, 33, or 36 surrounds the side surface of the block insulator BI.

The semiconductor layer SM functions as channels (current paths) of the memory cell transistors MT and the selection gate transistors DT and ST. In one example, each of the tunnel insulator TI and the block insulator BI includes silicon oxide. The charge accumulation film CA accumulates charges therein. In one example, the charge accumulation film CA includes silicon nitride.

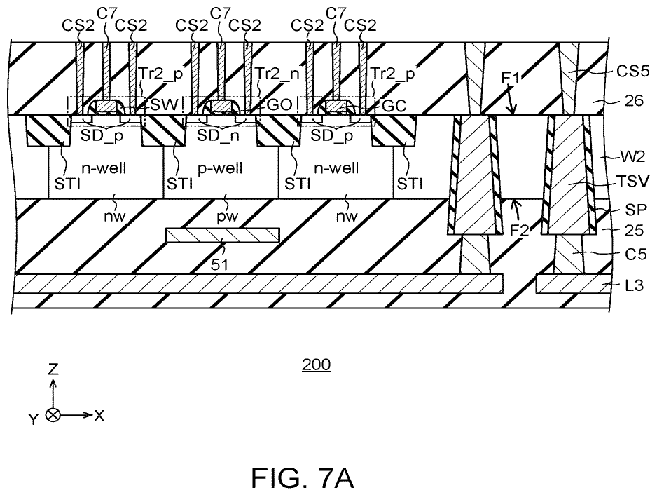

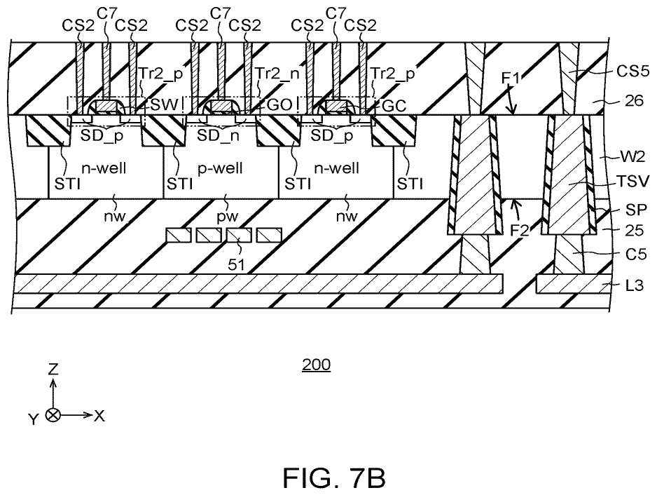

FIG. 7A is a sectional view illustrating a configuration example of the second structure 200 according to the first embodiment. FIG. 7A illustrates a structure of the substrate W2 of the second structure 200 and a peripheral part thereof.

The second structure 200 further includes shallow trench isolation parts STI, a p-well region (a first impurity diffused layer) pw, n-well regions (second impurity diffused layers) nw, and a conductor (wiring layer) 51. The numbers of the p-well region pw and the n-well regions nw are not limited to specific values.

The substrate W2 includes p-type (first conductivity type) impurities. examples of the p-type impurities include boron (B).

Each of the n-well regions nw is positioned between adjacent two of the shallow trench isolation parts STI. The n-well regions nw spread from the first surface F1 of the substrate W2 to the second surface F2 thereof. The n-well regions nw include n-type (second conductivity type) impurities. Examples of the n-type impurities include phosphorus (P) and arsenic (As).

The p-well region pw is positioned between adjacent two of the shallow trench isolation parts STI. The p-well region pw spreads from the first surface F1 of the substrate W2 to the second surface F2 thereof. The p-well region pw includes p-type impurities. In one example, the p-well region pw includes p-type impurities of a concentration equal to or higher than 1×10¹⁴ [atoms/cm³] and equal to or lower than 2×10¹⁶ [atoms/cm³] in a region including a boundary with the insulator 25. In one example, the concentration of the impurities is an average concentration.

Each of the shallow trench isolation parts STI is provided between adjacent ones of a plurality of transistors Tr2_p and Tr2_n. The shallow trench isolation parts STI are arranged on the side of the first surface F1 of the substrate W2 and are formed to extend in the −Z direction. In one example, the shallow trench isolation parts STI are configured of an insulating material such as silicon oxide, and each electrically isolate the source/drain region SD_p of the transistor Tr2_p and the source/drain region SD_n of the transistor Tr2_n from each other.

The conductor 51 is located between an associated conductor L3 and the p-well region pw. The conductor 51 is arranged to overlap at least a portion of the p-well region pw in a planar view seen from the Z direction. The conductor 51 may be arranged to overlap the whole of the p-well region pw in the planar view seen from the Z direction. Alternatively, the conductor 51 may be arranged in substantially the same region as the p-well region pw in a planar layout seen from the Z direction. As will be described later, the coverage of the p-well region pw (that is, the surficial area of the conductor 51) may be adjusted according to the voltage of the conductor L3, the impurity concentration of the p-well region pw, the distance between the conductor L3 and the p-well region pw, or the like.

For example, a conducting material such as a metallic line (for example, tungsten, copper, or aluminum) or doped polysilicon embedded in the insulator 25 is used as the conductor 51. The conductor 51 may be in an electrically floating state or may be connected to a node of a predetermined reference potential such as a ground potential. The conductor 51 is electrically separated from the p-well region pw, the n-well regions nw, and the conductor L3.

To prevent formation of a parasitic capacitance, it is desirable that the conductor 51 is arranged away from the p-well region pw. For example, the conductor 51 is arranged at a position 50 nm (nanometers) away from the p-well region pw.

The transistors Tr2 include p-type transistors Tr2_p and n-type transistors Tr2_n. The transistors Tr2_p and Tr2_n are MOSFETs constituting the CMOS described above.

Each of the transistors Tr2_p is arranged in an active area between adjacent two of the shallow trench isolation parts STI. Each of the transistors Tr2_p is positioned in an n-well region nw and above the n-well region nw, that is, on the side of the first surface F1 of the substrate W2. Each of the transistors Tr2_p includes a gate insulator GO, a gate electrode GC, and a region (source/drain region) SD_p of one pair of a source and a drain. The gate insulator GO is positioned on the upper surface of the substrate W2. In one example, the gate insulator GO includes silicon oxide. The gate electrode GC is positioned on the upper surface of the gate insulator GO. In one example, the gate electrode GC includes polysilicon that has a conductive property due to implantation of impurities. The source/drain region SD_p sandwiches a portion of a region, including the upper surface of the substrate W2, below the gate electrode GC. The source/drain region SD_p includes p-type impurities.

Each of the transistors Tr2_n is arranged in an active area between adjacent two of the shallow trench isolation parts STI. Each of the transistors Tr2_n is positioned in a p-well region pw and above the p-well region pw, that is, on the side of the first surface F1 of the substrate W2. Each of the transistors Tr2_n includes a gate insulator GO, a gate electrode GC, and a region (source/drain region) SD_n of one pair of a source and a drain. The source/drain region SD_n sandwiches a portion of a region, including the upper surface of the substrate W2, below the gate electrode GC. The source/drain region SD_n includes n-type impurities.

The transistors Tr2_p and Tr2_n can be constituted of an LV (Low Voltage) transistor having a relatively low threshold voltage and a VLV (very Low Voltage) transistor having a lower threshold voltage. In this case, the n-well regions nw and the p-well region pw are formed to have relatively low impurity concentrations, and the p-well region pw (or the n-well regions nw) is in a state of being easily inverted by application of a voltage from outside.

For example, in a case of a stacked structure including the first to third structures 100 to 300 as illustrated in FIG. 5, there is a case where a conductor L3 connected to the first or third structure 100 or 300 via a through-electrode TSV is arranged near the substrate W2. When a high voltage (for example, 30V) is applied to such a conductor L3, an inverted layer is sometimes formed in a region of the associated p-well region pw on the side of the lower surface of the substrate W2. In this case, there is a problem that adjacent n-well regions nw are electrically connected by the inverted layer formed in the p-well region pw and a leak current is accordingly generated.

In the present embodiment, to solve this problem, the conductor 51 can be used as a shield line. With the conductor 51, an electric field of the conductor L3 can be shielded, application of the voltage of the conductor L3 to the p-well region pw can be prevented, and generation of a leak current due to formation of an inverted layer can be suppressed. In this case, the conductor 51 may cover a part or the whole of the n-well regions nw in addition to the p-well region pw in the planar view seen from the Z direction.

It is desirable that the conductor 51 covers the p-well region pw at least to such an extent that the inverted layer that can be formed in the p-well region pw does not electrically connect n-well regions nw adjacent to the p-well region pw to each other. In other words, it is adequate that the coverage with the conductor 51 of the p-well region pw is large enough to prevent the inverted layer formed in the p-well region from extending from one n-well region nw to reach another n-well region nw.

The coverage with the conductor 51 of the p-well region pw may be adjusted according to the voltage of the conductor L3 or the impurity concentration of the p-well region pw. For example, in a case where a high voltage is applied to the conductor L3, it is expected that a larger inverted layer is formed in the p-well region pw. Accordingly, it is desirable that the coverage with the conductor 51 of the p-well region pw is increased, that is, the surficial area of the conductor 51 is increased. Similarly, in a case where the impurity concentration of the p-well region pw is low, the distance between the conductor L3 and the p-well region pw is short, or the like, it is desirable that the coverage with the conductor 51 of the p-well region pw is increased. In a case where a voltage applied to the conductor L3 is relatively low, a case where the impurity concentration of the p-well region pw is high, a case where the distance between the conductor L3 and the p-well region pw is long, or the like, the coverage with the conductor 51 of the p-well region pw may be decreased to reduce the formation cost of the conductor 51.

When a low voltage is applied to the conductor L3, an inverted layer is sometimes formed in the n-well regions nw. to suppress this, conductors

each overlapping a portion of an associated one of the n-well regions nw in the planar view seen from the Z direction may be arranged in the second structure 200. This enables a leak current caused by connection of adjacent p-well regions pw with the inverted layer to be suppressed similarly to the conductor 51. The coverage with the conductor 51 of the associated n-well region nw may be adjusted according to the voltage of the conductor L3 or the impurity concentration of the n-well regions nw, or the like, as described above.

Each of the contacts CS2, CS5, and C7 and the shallow trench isolation parts STI has a tapered shape. The area of each of the contacts CS2, CS5, and C7 and the shallow trench isolation parts STI in the XY plane is larger at the upper end than at the lower end, and decreases from the upper end to the lower end (in the −Z direction) in one example.

Each of the through-electrodes TSV, the insulators SP, and the contacts C5 has an inverse tapered shape. The area of each of the through-electrodes TSV, the insulators SP, and the contacts C5 in the XY plane is smaller at the upper end than at the lower end, and increases from the upper end to the lower end (in the −Z direction) in one example.

FIG. 7B is a sectional view illustrating a configuration example of a second structure 200 according to a modification of the first embodiment. In the present modification, the conductor 51 is divided into plural pieces. The plural conductors 51 extend in the ±Y directions, are arrayed in the ±X directions, and are each configured in a strip shape. The insulator 25 is located between the conductors 51. In the present modification, although the conductors 51 do not cover the whole of the p-well region pw in the planar view seen from the Z direction, the conductors 51 can shield the electric field of the conductor L3 to some extent. The rest of the configuration in the present modification can be the same as that in the first embodiment.

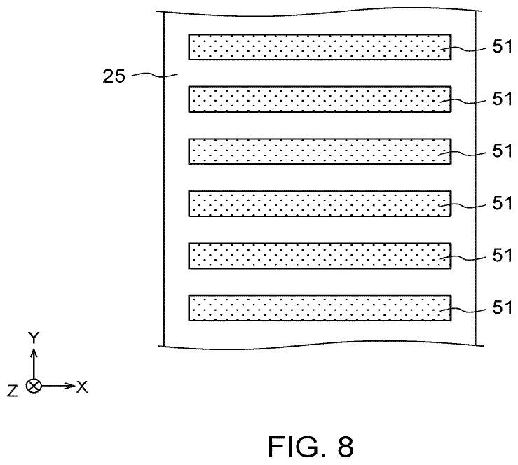

FIG. 8 is a plan view of a configuration example of a second structure 200 according to another modification of the first embodiment. FIG. 8 illustrates a plan view of the insulator 25 and the conductors 51 in an extracted manner. A sectional view of this modification can be the same as that of FIG. 7A. As illustrated in FIG. 8, a plurality of conductors 51 in a strip shape may extend in the ±X directions and be arrayed in the ±Y directions. Also in this case, similarly in the modification illustrated in FIG. 7B, the conductors 51 can shield the electric field of the conductor L3 to some extent although the conductors do not cover the whole of the p-well region pw in the planar view seen from the Z direction. The rest of the configuration of the present modification can be the same as that in the first embodiment. The conductors 51 are not limited to those described above and may be formed to extend in the ±Y directions.

A manufacturing method of the storage device 1 according to the first embodiment is described next.

A manufacturing process of the storage device 1 includes a process of individually manufacturing the first structure 100, the second structure 200, and the third structure 300, and a process of bonding the manufactured first, second, and third structures 100, 200, and 300 to each other. A manufacturing method of the second structure 200 according to the present embodiment is described below.

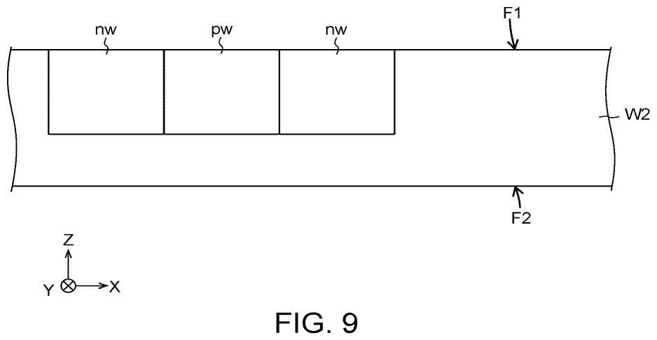

FIGS. 9 to 16 are sectional views illustrating one example of the manufacturing method of the second structure 200 of the storage device according to the first embodiment.

As illustrated in FIG. 9, the n-well regions nw and the p-well regions pw are formed on the substrate W2 using a lithography technique and an ion implantation technique. The substrate W2 is, for example, a semiconductor substrate such as a silicon substrate. The n-well regions nw are formed, for example, by implanting n-type impurities such as phosphorus (P) or arsenic (As) from the first surface F1. The p-well regions pw are formed, for example, by implanting p-type impurities such as boron (B) from the first surface F1. The n-well regions nw and the p-well regions pw are formed adjacently to each other.

Either the n-well regions nw or the p-well regions pw can be formed first.

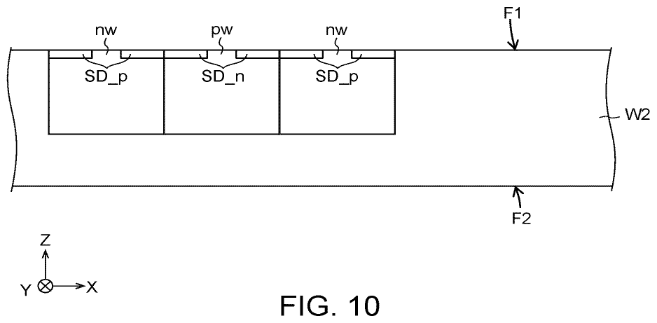

Next, as illustrated in FIG. 10, the source/drain regions SD_n and SD_p are formed on the substrate W2 using a lithography technique and an ion implantation technique. The source/drain regions SD_n are formed, for example, by implanting n-type impurities such as phosphorus (P) or arsenic (As) in the p-well regions pw from the first surface F1. The source/drain regions SD_p are formed, for example, by implanting p-type impurities such as boron (B) in the n-well regions nw from the first surface F1.

Either the source/drain regions SD_n or SD_p can be formed first.

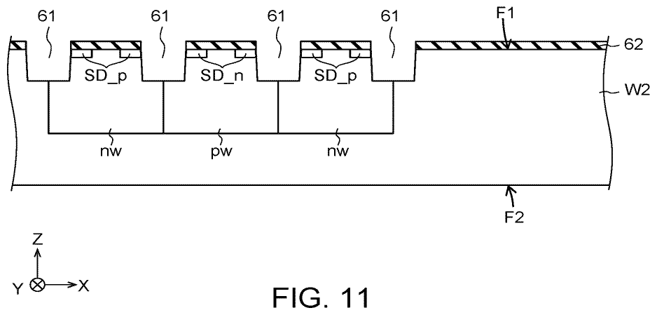

Next, trenches 61 are formed as illustrated in FIG. 11. The trenches 61 occupy a region where the shallow trench isolation parts STI are expected to be formed. The trenches 61 are formed, for example, by a photolithography process and anisotropic etching. For example, RIE (Reactive Ion Etching) is applicable as the anisotropic etching.

As a specific process, first, a material for a hard mask 62 is deposited on the first surface F1. The material for the hard mask 62 located in the formation region for the shallow trench isolation parts STI is selectively removed by a lithography technique and an etching technique. Accordingly, the hard mask 62 has openings above the region where the shallow trench isolation parts STI are expected to be formed, and the first surface F1 of the substrate W2 is exposed in the openings.

The substrate W2 is etched in the −Z direction by an etching technique such as the RIE method or the like using the hard mask 62 as a mask. Accordingly, the trenches 61 are formed in the formation region for the shallow trench isolation parts STI. The side surface of each of the trenches 61 tapers in such a manner as to approach the center of the trench 61 in the −Z direction.

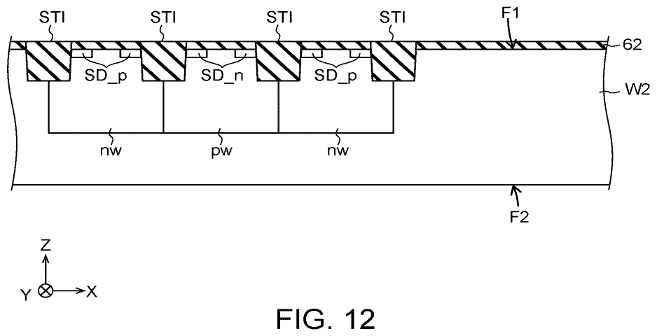

Next, the shallow trench isolation parts STI are formed as illustrated in FIG. 12. Specifically, for example, an insulating material for the shallow trench isolation parts STI is deposited on the substrate W2 by a CVD (Chemical Vapor Deposition) method or the like, and is polished by a CMP (Chemical Mechanical Polishing) method or the like. The shallow trench isolation parts STI are thereby formed in the trenches 61.

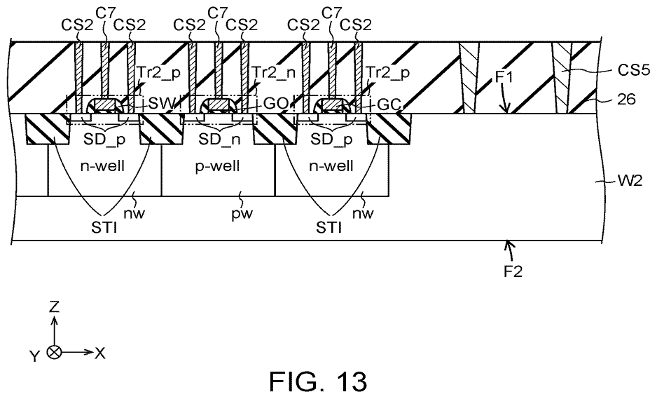

Next, after the hard mask 62 is removed, the gate insulators GO, the gate electrodes GC, sidewall insulators SW, the insulator 26, and the contacts CS2, CS5, and C7 are formed as illustrated in FIG. 13.

For example, the gate insulators GO can be formed by a thermal oxidation method. The gate electrodes GC can be formed, for example, by depositing a material for the gate electrodes GC by the CVD method and subsequently processing the material using a photolithography process and anisotropic etching. The sidewall insulators SW can be formed by depositing a material for the sidewall insulators SW by the CVD method and subsequently anisotropically etching back the material.

Next, the insulator 26 is deposited on a structure of the gate electrodes GC and the like.

Next, contact holes for the contacts CS2, CS5, and C7 are formed using a lithography technique and an etching technique. Next, a conductive material is filled in the contact holes, whereby the contacts CS2, CS5, and C7 are formed.

Next, the second surface F2 of the substrate W2 is polished using the CMP method or the like as illustrated in FIG. 14. At that time, the third structure 300 formed separately from the second structure 200 is bonded to the insulator 26 on the side of the first surface F1 of the substrate W2. A support substrate may be bonded instead of the third structure 300. FIG. 14 illustrates a structure obtained by vertically inverting the structure illustrated in FIG. 13 in the Z direction.

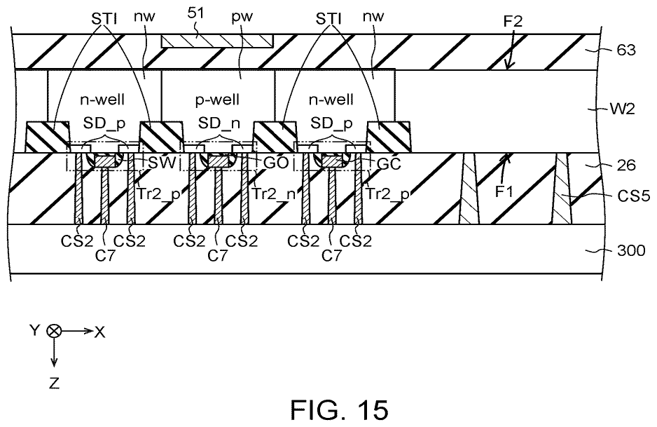

Next, an insulating material for an insulator 63 is deposited on the side of the second surface F2 of the substrate W2 as illustrated in FIG. 15. The insulator 63 is a part of the insulator 25 formed in a subsequent process.

Next, the conductor 51 is formed on the side of the second surface F2 of the substrate W2 by a damascene method or the like as illustrated in FIG. 15. Specifically, the insulator 63 located in the formation region for the conductor 51 is first selectively removed using a lithography technique and an etching technique. Next, a material (for example, tungsten) for the conductor 51 is deposited on the insulator 63. Next, the material for the conductor 51 is polished using the CMP method or the like until the surface of the insulator 63 is exposed. The conductor 51 is thereby formed in the insulator 63.

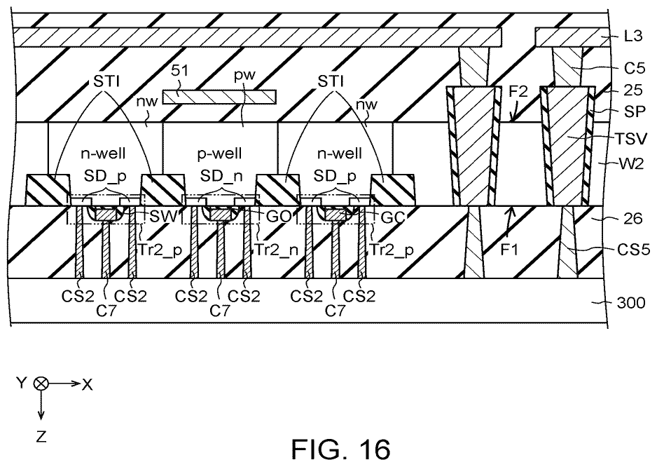

Next, an insulating material for the insulator 25 is further deposited on the side of the second surface F2 of the substrate W2 as illustrated in FIG. 16. Through-holes for the through-electrodes TSV penetrating through the insulator 25 and the substrate W2 are formed by a lithography technique and an etching technique. Each of the through-holes extends from the side of the second surface F2 of the substrate W2 to the side of the first surface F1 to reach an associated contact CS5. Since the through-holes are formed in the +Z direction from the side of the second surface F2 of the substrate W2 to the side of the first surface F1, the width of each of the through-holes in the XY plane decreases from the side of the second surface F2 of the substrate W2 to the side of the first surface F1 in the +Z direction. The area of each of the through-holes in the XY plane decreases from the side of the second surface F2 to the side of the first surface F1 in the +Z direction. That is, the side surface of each of the through-holes tapers in such a manner as to approach the center of the through-hole in the +Z direction. A conductive material is embedded in the through-holes, whereby the through-electrodes TSV are formed.

Subsequently, an insulating material for the insulator 25 is further deposited on the side of the second surface F2 of the substrate W2, and the contacts C5, conductors L3, the insulator 24, the contacts C4, the joint terminals BP2L (see FIG. 5), and the like are formed. The second structure 200 is thereby obtained.

Subsequently, the first structure 100 manufactured separately from the second structure 200 is bonded to the second structure 200 on the side of the second surface F2. In a case where the support substrate has been bonded to the second structure 200 on the side of the first surface F1, the support substrate is detached and the third structure 300 is bonded to the second structure 200 on the side of the first surface F1. By dicing the bonded first to third structures 100 to 300, the structures are singulated into semiconductor chips including the first to third structures 100 to 300. The storage device 1 according to the present embodiment is thereby formed.

According to the first embodiment, the conductor 51 is arranged between the associated conductor L3 and the associated p-well region pw in such a manner as to overlap at least a portion of the p-well region pw in a planar view seen from the Z direction. With use of the conductor 51 as a shield line, formation of an inverted layer in the p-well region pw due to an electric field of the conductor L3 can be prevented. Accordingly, a leak current between the n-well regions nw or between the transistors Tr2_p can be suppressed more reliably.

To suppress a leak current between p-well regions pw or between transistors Tr2_n, a conductor may be arranged between a conductor L3 and an associated n-well region nw in such a manner as to overlap at least a portion of the n-well region nw in a planar view seen from the Z direction.

### Second Embodiment

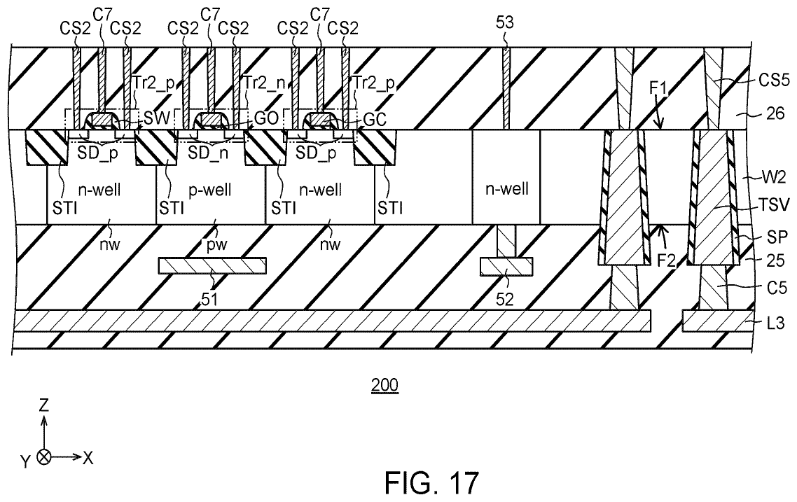

FIG. 17 is a sectional view illustrating a configuration example of a second structure 200 according to a second embodiment. In the second embodiment, a back-gate bias of the transistor Tr2_n is controlled by the conductor 51.

The second structure 200 further includes a conductor 52 and a contact 53. The conductor 52 is formed, for example, to be embedded in the insulator 25. The conductor 52 is electrically connected to the conductor 51 by a line (not illustrated) or the like. The conductor 52 is electrically connected to, for example, an n-well region nw. The contact 53 is connected to, for example, the n-well region nw from the side of the first surface F1 of the substrate W2.

The conductor 52 can be formed, for example, by the same process and in the same layer as the conductor 51 in the process described with reference to FIG. 15.

The contact 53 is connected to, for example, the voltage generation circuit or the like in the first structure 100. The voltage generation circuit applies a predetermined bias voltage to the conductor 51 via the contact 53, the n-well region nw, and the conductor 52. Accordingly, the conductor 51 can control the voltage of the associated p-well region pw (that is, the back-gate bias of the associated transistor Tr2_n) on the basis of the bias voltage.

Similarly, in a case where the second structure 200 includes a conductor (not illustrated) between a conductor L3 and an associated n-well region nw, this conductor may be used for control of a back-gate bias of the associated transistors Tr2_p.

### Third Embodiment

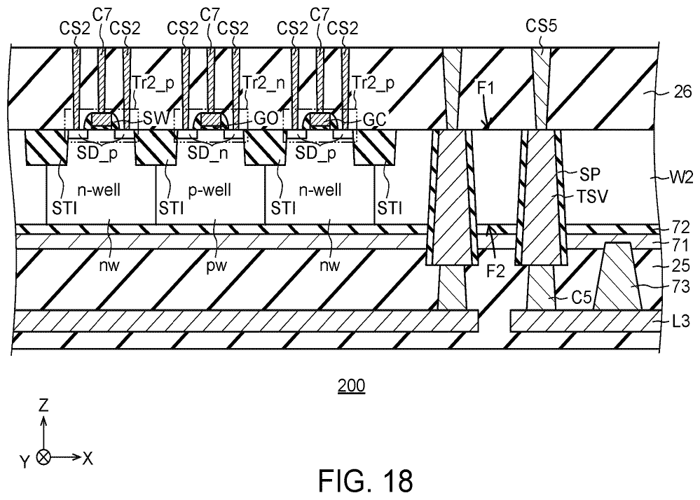

FIG. 18 is a sectional view illustrating a configuration example of a second structure 200 according to a third embodiment. In the third embodiment, a semiconductor layer (conductor) 71 and an insulator 72 are arranged instead of the conductor 51.

The semiconductor layer 71 is arranged on the side of the second surface F2 of the substrate W2. The semiconductor layer 71 is arranged, for example, to overlap substantially the whole surface of the second surface F2 of the substrate W2 in a planar view seen from the Z direction. The semiconductor layer 71 is, for example, formed of silicon (Si) including n-type impurities such as phosphorus (P) or arsenic (As) (that is, a diffused layer). Instead of the n-type impurities described above, p-type impurities such as boron (B) may be implanted in the semiconductor layer 71. The impurity concentration of the semiconductor layer 71 is, for example, equal to or higher than 5×10²⁰ [atoms/cm³].

The insulator 72 is arranged between the semiconductor layer 71 and the second surface F2 of the substrate W2. The insulator 72 insulates the semiconductor 71 from the p-well region pw and the n-well regions nw of the substrate W2.

The semiconductor layer 71 suppresses application of a voltage of the conductor L3 to the p-well region pw similarly to the conductor 51. When a high voltage is applied to the conductor L3, an inverted layer is formed in the semiconductor layer 71. Meanwhile, the p-well region pw is guarded by the semiconductor layer 71 and an inverted layer is not formed therein even when a high voltage is applied to the conductor L3. Accordingly, a leak current can be suppressed. The insulator 72 can suppress a depleted layer formed in each of the transistors Tr2 from reaching the semiconductor layer 71.

The second structure 200 further includes a contact 73. The contact 73 is formed to extend in the +Z direction from a conductor L3 to reach the semiconductor layer 71. The contact 73 electrically connects the conductor L3 to the semiconductor layer 71. The contact 73 releases (discharges) charges accumulated in the semiconductor layer 71 to a node of a predetermined reference potential such as a ground potential. Alternatively, the contact 73 keeps the semiconductor layer 71 at a predetermined voltage (for example, ground). In a case where the semiconductor layer 71 is formed in an electrically floating state, the contact 73 may be omitted.

As described above, the conductor 71 is provided as a SOI (Silicon-On-Insulator) layer on the second surface F2 of the substrate W2. Therefore, the semiconductor layer 71 and the insulator 72 arranged on the second surface F2 of the substrate W2 are also referred to as “SOI structure”. Since impurities are implanted in the semiconductor layer 71 as described above, this is also referred to as “Doped-SOI structure”.

Implantation of impurities in the semiconductor layer 71 enables the thickness of the semiconductor layer 71 to be smaller relative to that in a SOI structure in which impurities are not implanted.

In a case where a low voltage is applied to the conductors L3, the semiconductor layer 71 may suppress formation of an inverted layer in the n-well regions nw.

A conductive layer such as a metallic layer may be arranged instead o the semiconductor layer 71 in the second structure 200 so as to overlap substantially the whole surface of the second surface F2 of the substrate W2 in the planar view seen from the Z direction.

A manufacturing method of the storage device 1 according to the third embodiment is described next.

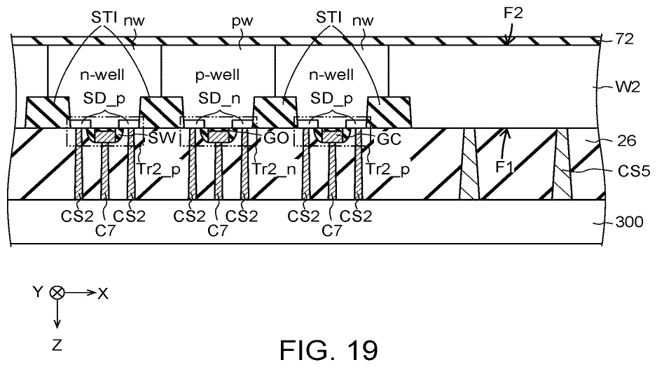

FIGS. 19 to 21 are sectional views illustrating one example of a manufacturing method of the second structure 200 of the storage device according to the third embodiment. A process illustrated in FIG. 19 is a process subsequent to the process of FIG. 14 described in the first embodiment.

First, the insulator 26, the contacts CS5, and the transistors Tr2_p and Tr2_n are formed in the processes illustrated in FIGS. 9 to 13 similarly in the first embodiment. The second surface F2 of the substrate W2 is polished in the process illustrated in FIG. 14.

Next, a film of the insulator 72 is formed on the second surface F2 of the substrate W2 as illustrated in FIG. 19.

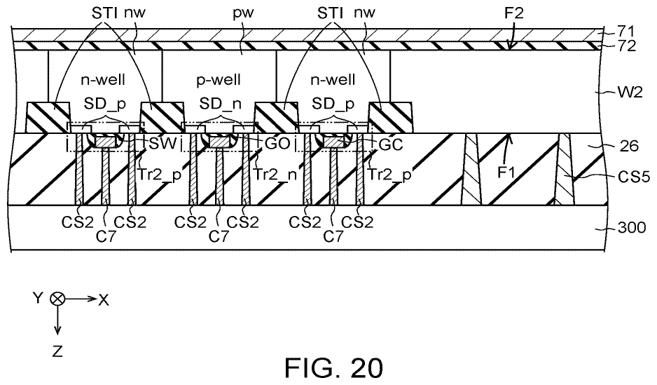

Next, as illustrated in FIG. 20, a film of silicon is formed on the insulator 72 and impurities are implanted therein, whereby the semiconductor layer 71 is formed.

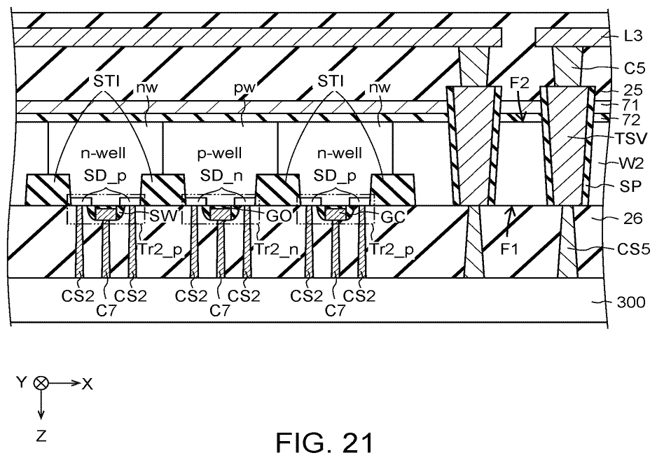

Next, as illustrated in FIG. 21, an insulating material for the insulator 25 is deposited on the side of the second surface F2 of the substrate W2. The through-electrodes TSV, the contacts C5, the conductors L3, the insulator 24, the contacts C4, the joint terminals BP2L, and the like are formed in the same process as that illustrated in FIG. 16. The contact 73 can be formed in the same process as that of the contacts C5, or before or after this process. The second structure 200 is thereby obtained. The storage device 1 according to the present embodiment is formed by bonding of the first structure 100 and the third structure 300, a dicing process, and the like.

According to the third embodiment, the semiconductor layer 71 and the insulator 72 are arranged to overlap substantially the whole surface of the substrate W2 on the side of the second surface F2 in the planar view seen from the Z direction. The semiconductor layer 71 includes n-type (or p-type) impurities. The semiconductor layer 71 can suppress formation of an inverted layer in the p-well region pw (or the n-well regions nw) due to an electric field of the conductor L3. Accordingly, a leak current can be suppressed more reliably. The semiconductor layer 71 and the insulator 72 according to the third embodiment can be formed at a lower cost than that of the conductor 51 formed using the damascene method in the first embodiment.

### Fourth Embodiment

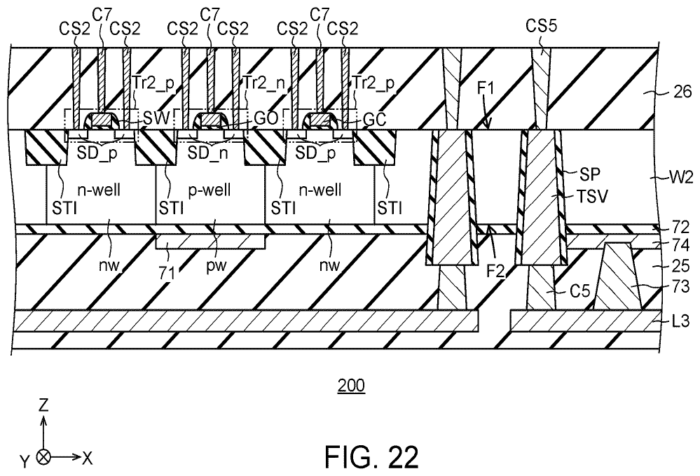

FIG. 22 is a sectional view illustrating a configuration example of a second structure 200 according to a fourth embodiment. In the fourth embodiment, the semiconductor layer 71 is arranged to overlap at least a portion of the p-well region pw or the whole of the p-well region pw without being arranged to overlap substantially the whole surface of the second surface F2 of the substrate W2 in the planar view seen from the Z direction. Similarly in the first embodiment, the coverage with the semiconductor layer 71 of the p-well region pw (that is, the surficial area of the semiconductor layer 71) may be adjusted according to the voltage of the conductor L3, the impurity concentration of the p-well region pw, the distance between the conductor L3 and the p-well region pw, or the Like.

In a case where a plurality of p-well regions pw are provided, a plurality of semiconductor layers 71 may be arranged away from each other for the p-well regions pw, respectively.

A semiconductor layer 74 in the same layer as the semiconductor layer 71 is arranged to be connected to the contact 73. The semiconductor layer 71 and the semiconductor layer 74 are electrically connected by a line, a semiconductor layer, or the like (not illustrated). With the semiconductor layer 74, charges accumulated in the semiconductor layer 71 can be released to a node of a predetermined reference potential such as a ground potential. Alternatively, the semiconductor layer 74 can keep the semiconductor layer 71 at a predetermined voltage (for example, ground) via the contact 73 and the like. In a case where the semiconductor layer 71 is formed in an electrically floating state, the semiconductor layer 74 can be electrically separated from the semiconductor layer 71.

A manufacturing method of the storage device 1 according to the fourth embodiment is described next.

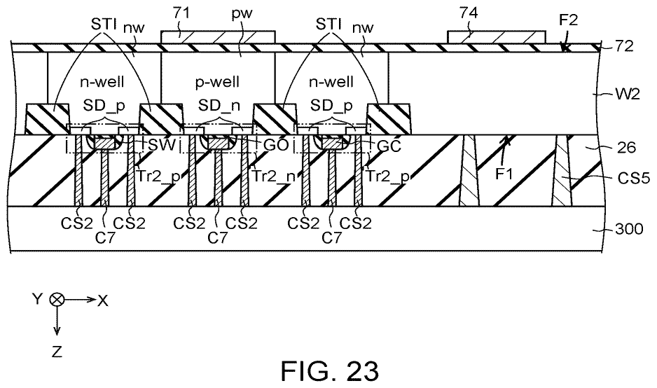

FIG. 23 is a sectional view illustrating one example of a manufacturing method of the second structure 200 of the storage device according to the fourth embodiment. A process illustrated in FIG. 23 is a process subsequent to the process of FIG. 20 described in the third embodiment.

In the process of FIG. 23, after the semiconductor layer 71 is formed in the process of FIG. 20, a part of the semiconductor layer 71 is removed. Specifically, a part of the semiconductor layer 71 is selectively removed by a lithography technique and an etching technique such as RIE using a patterned mask material or the like. The semiconductor layer 71 is connected to the contact 73 and the like by forming lines and the like (not illustrated).

After the process of FIG. 23, the second structure 200 and the storage device 1 are formed in the same process as that illustrated in FIG. 21.

In the fourth embodiment, the semiconductor layer 71 is not formed around each of the through-electrodes TSV. Accordingly, generation of an unexpected parasitic capacitance between each of the through-electrodes TSV and the semiconductor layer 71 can be suppressed.

### Fifth Embodiment

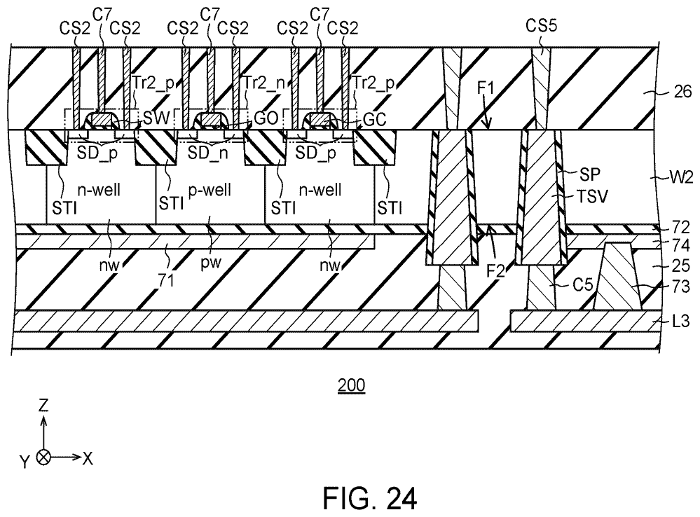

FIG. 24 is a sectional view illustrating a configuration example of a second structure 200 according to a fifth embodiment. In the fifth embodiment, the semiconductor layer 71 is formed at a portion of the second surface F2 of the substrate W2 other than a peripheral region near each of the through-electrodes TSV. In the fifth embodiment, similarly in the fourth embodiment, generation of an unexpected parasitic capacitance between each of the through-electrodes TSV and the semiconductor layer 71 can be suppressed.

The semiconductor layer 71 of the fifth embodiment can be formed using a lithography technique and the like as in FIG. 23. The semiconductor layer 71 of the fifth embodiment can reduce the exposure amount in lithography and can be formed at a lower cost relative to the fourth embodiment.

### Sixth Embodiment

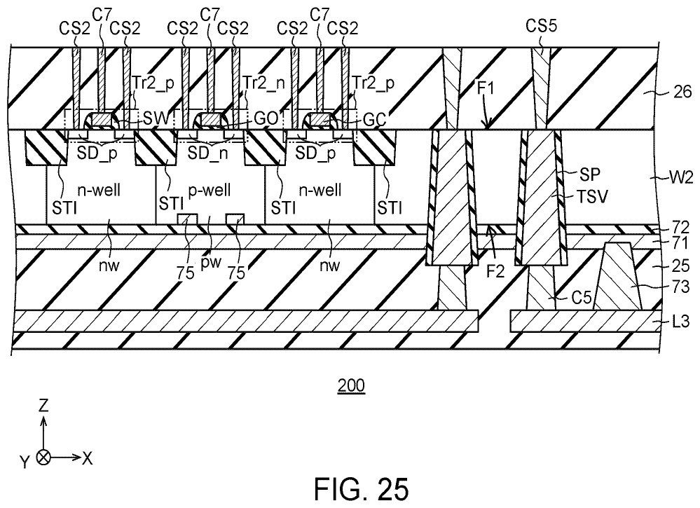

FIG. 25 is a sectional view illustrating a configuration example of a second structure 200 according to a sixth embodiment. In the sixth embodiment, a plurality of diffused layers 75 are arranged in the p-well region pw on the side of the second surface F2. The diffused layers 75 are, for example, n-type diffused layers including n-type impurities such as phosphorus (P) or arsenic (As) implanted therein. The semiconductor layer 71 is, for example, non-doped silicon including no impurities implanted therein.

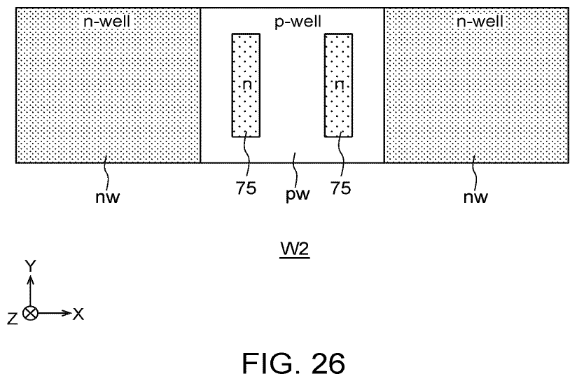

FIG. 26 is a plan view of a substrate W2 according to the sixth embodiment. FIG. 26 illustrates the substrate W2 seen from the lower surface. FIG. 26 also illustrates a plurality of n-well regions nw, a p-well region pw, and a plurality of diffused layers 75. The diffused layers 75 are, for example, rectangular regions arrayed in the X direction and each extending in the Y direction.

Due to a back surface field produced by the diffused layers 75 arranged in the p-well region pw, an inverted layer can be formed in the semiconductor layer 71. Accordingly, in the sixth embodiment, the semiconductor layer 71 can be used as a shield line that guards the p-well region pw without implantation of impurities in the semiconductor layer 71 (a Non-doped SOI structure).

### Seventh Embodiment

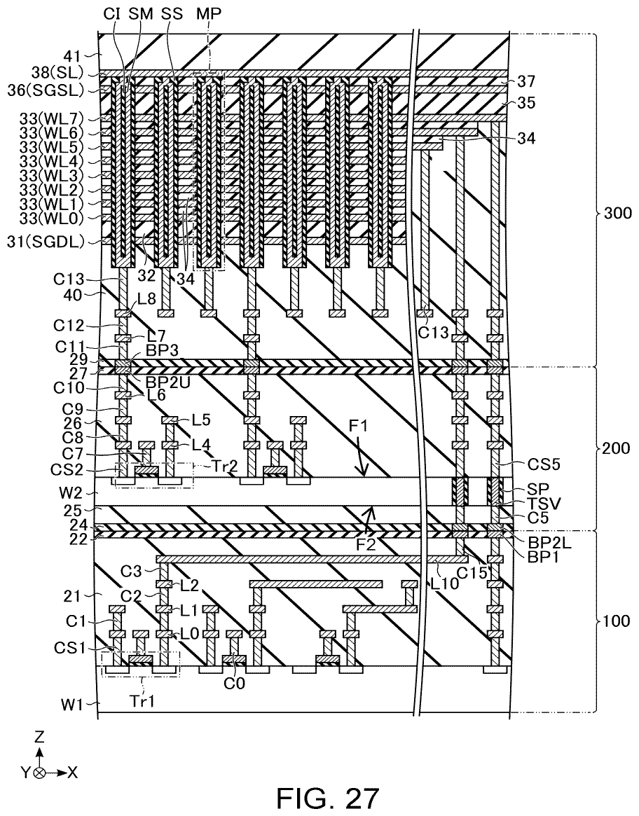

FIG. 27 is a sectional view illustrating a configuration example of a storage device according to a seventh embodiment. In the seventh embodiment, instead of the conductors L3, conductors L10 that face the p-well regions pw and transmit a positive high voltage are positioned in the first structure 100.

The second structure 200 does not include the conductors L3 and the contacts C4. Meanwhile, the first structure 100 further includes the conductors L10 and contacts C15.

Each of the contacts C5 is in contact on the lower surface on the side of the second surface F2 with the upper surface of a joint terminal BP2L. Each contact C3 is in contact on the upper surface with the lower surface of one conductor L10. Each contact C15 is in contact on the lower surface with the upper surface of one conductor L10. Each contact C15 is in contact on the upper surface with the lower surface of one joint terminal BP1. The conductors L10 can receive a positive high voltage or a negative high voltage similarly to the conductors L3. Therefore, when the thickness of the insulator 25 and the thickness of a portion of the insulator 21 upper than the upper surfaces of the conductors L10 are small and the conductors L10 are close to the substrate W2, there is a risk that the p-well regions pw are inverted.

However, in the seventh embodiment, the conductor 51 is arranged between the conductor L10 and the p-well region pw (or the n-well regions nw) to overlap at least a portion of the p-well region pw (or the n-well regions nw) in the planar view seen from the Z direction similarly in the first or second embodiment. Alternatively, the seventh embodiment includes a SOI structure including the semiconductor layer 71 arranged to overlap at least the p-well region pw (or the n-well regions nw) in the planar view seen from the Z direction similarly in the third to sixth embodiments. Accordingly, the seventh embodiment can obtain the same effects as those of any of the first to sixth embodiments.

The foregoing descriptions are based on the examples in which the semiconductor device of the embodiments described above is a storage device. The embodiments described above are applicable to structures that are bonded to each other and that include the transistors Tr2 and the conductors L3 (or L10) as the first structure 100 and the second structure 200. Examples of such other semiconductor devices include an image sensor and ICs (Integrated Circuits). In this case, the third structure 300 is not provided. Alternatively, the third structure 300 has semiconductor elements other than a memory cell array.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a first structure comprising a plurality of first semiconductor elements formed therein;
a second structure comprising a substrate comprising a plurality of impurity diffused layers, and a plurality of second semiconductor elements located in the impurity diffused layers on a side of a first surface of the substrate, and the second structure being stacked on the first structure on a side of a second surface of the substrate on an opposite side to the first surface;
a first conductor located between the first structure and the second structure, electrically separated from the substrate, and electrically connected to at least one of the first semiconductor elements; and
a second conductor located between the first conductor and the impurity diffused layers, and shielding at least a portion of the impurity diffused layers from an electric field of the first conductor.

2. The device of claim 1, wherein
the impurity diffused layers comprise a first impurity diffused layer comprising impurities of a first conductivity type, and a plurality of second impurity diffused layers comprising impurities of a second conductivity type and arranged to sandwich the first impurity diffused layer in the first surface, and
the second conductor overlaps at least a portion of the first impurity diffused layer in a planar view from a stacking direction of the first and second structures.

3. The device of claim 2, further comprising a first insulator located between the first conductor and the substrate, wherein
the second conductor is arranged in the first insulator.

4. The device of claim 2, wherein the second conductor overlaps substantially a whole surface of the first impurity diffused layer in the planar view from the stacking direction.

5. The device of claim 2, wherein the second conductor partially overlaps the first impurity diffused layer in the planar view from the stacking direction.

6. The device of claim 2, wherein the second conductor controls a voltage of the first impurity diffused layer.

7. The device of claim 2, comprising a second insulating layer located between the second conductor and the substrate, wherein
the second conductor comprises a semiconductor layer comprising impurities of the second conductivity type or the first conductivity type.

8. The device of claim 7, wherein the semiconductor layer overlaps substantially a whole surface of the substrate in the planar view from the stacking direction.

9. The device of claim 7, wherein the semiconductor layer overlaps at least a portion of the first impurity diffused layer in the planar view from the stacking direction.

10. The device of claim 7, comprising a through-electrode electrically connected to the first conductor, penetrating through the substrate in the stacking direction, and electrically separated from the substrate, wherein
the semiconductor layer overlaps the substate in a region other than a peripheral region near the through-electrode in the planar view seen from the stacking direction.

11. The device of claim 2, further comprising a plurality of fourth impurity diffused layers arranged in the first impurity diffused layer on a side of the second surface and comprising impurities of the second conductivity type, wherein
the second conductor comprises a semiconductor layer comprising an inverted layer based on an electric field of the fourth impurity diffused layers.

12. The device of claim 1, wherein the second conductor is in an electrically floating state.

13. The device of claim 1, wherein the second conductor is kept at a predetermined voltage.

14. The device of claim 1, further comprising a third structure stacked on the second structure on a side of the first surface and comprising a memory cell array.

15. The device of claim 14, wherein
the memory cell array comprises
a stacked body comprising a plurality of second conductors and a plurality of second insulators stacked alternately one by one, and
a plurality of columnar bodies each comprising a semiconductor layer penetrating through the stacked body and a memory layer located between the stacked body and the semiconductor layer, and constituting memory cells at intersecting positions with the second conductors, and
the first structure comprises a plurality of first transistors each electrically connected to any of the second conductors.

16. The device of claim 15, wherein the first transistors constitute a drive circuit configured to control a voltage to be applied to any of the second conductors.

17. The device of claim 15, wherein the second structure comprises a plurality of second transistors each electrically connected to the semiconductor layer of any of the columnar bodies.

18. The device of claim 17, wherein the second transistors constitute a detection circuit configured to detect data stored in the memory cells.

19. The device of claim 17, wherein
the second semiconductor elements constitute a CMOS (Complementary Metal Oxide Semiconductor) circuit, and
the second semiconductor elements comprise the second transistor of a second conductivity type located in a first impurity diffused layer of a first conductivity type, and the second transistor of a first conductivity type located in a second impurity diffused layer of a second conductivity type.

20. A manufacturing method of a semiconductor device, the method comprising:
forming first well regions of a first conductivity type and second well regions of a second conductivity type in a substrate on a side of a first surface;
forming a plurality of first semiconductor elements in the first and second well regions on the side of the first surface;
forming a first insulator on a second surface of the substrate on an opposite side to the first surface;
forming a second conductor on the first insulator so as to overlap at least a portion of an associated one of the first well regions in a planar view seen from a first direction from the second surface to the first surface;
depositing the first insulator or a second insulator on the second conductor; and
forming or arranging a first conductor to sandwich the second conductor with the associated first well region.
